(19) United States
(12) Patent Application Publication
(10) Pub. No.: US 2024/0267449 A1
(43) Pub. Date: Aug. 8, 2024

(54) SYSTEM FOR REPLACING A DEVICE SCREEN

(71) Applicants: Emiliano German Solazzi Griminger, Arlington, VA (US); Viviana Lemos, Arlington, VA (US)

(72) Inventors: Emiliano German Solazzi Griminger, Arlington, VA (US); Viviana Lemos, Arlington, VA (US)

(21) Appl. No.: 18/106,986

(22) Filed: Feb. 7, 2023

(51) Int. Cl. H04M 1/02; H05K 1/18

(52) U.S. Cl. CPC H04M 1/0266; H05K 1/189

(57) ABSTRACT

A method of screen replacement for an electronic device such as a cellphone is disclosed, by which the user can easily detach the screen without applying external tools for opening the phone, detaching cables, and exposing the internal components of the phone to damage. The user will be able to quickly and conveniently replace a damaged screen with a replacement display screen using a pre-configured quick release assembly for the cellphone.

### BACKGROUND

### Technical Field

This disclosure relates to repair and upgrade methods for electronics. In particular, but without limitation, the disclosure relates to a method for repairing and/or upgrading screens on electronic devices.

Repair and upgrade techniques for electronic devices are known in the art.

CN 210007744 discloses a cell phone screen convenient for replacement and assembly.

However, the prior art techniques tend to make a repaired electronic device bulkier or remove water-proof features of the original electronic device, are inconvenient or cause other disadvantages due to the repair or upgrade process used on the electronic device.

### COPYRIGHT NOTICE

A portion of the disclosure of this patent document contains material, which is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### SUMMARY

An electronic device screen assembly of an electronic device for convenient replacement is disclosed. The electronic device screen assembly includes a display screen module; a sensor in communication with the display screen module, the sensor configured to direct the electronic device to release the display screen module; a separator in communication with the display screen module and positioned below the display screen module; a heat resistant plastic rim in communication with an inner contour frame of the electronic device; the heat resistant plastic rim configured to accept the display screen module; a heat cover in communication with the electronic device; and one or more pin connector modules configured to connect the electronic device with the display screen module.

In an aspect, a method for replacing a display screen on an electronic device without use of external tools is disclosed. The method includes preparing the display screen of the electronic device for removal with a sensor configured to direct the electronic device to release the display screen; removing the display screen from the electronic device; inserting a replacement display screen module onto the electronic device.

Other systems, methods, features and advantages of the disclosure will be, or will become, apparent to one with skill in the art upon examination of the following figures and detailed description. It is intended that all such additional systems, methods, features and advantages be included within this description, be within the scope of the disclosure, and be protected by the following claims.

### BRIEF DESCRIPTION OF THE DRAWINGS

The disclosure can be better understood with reference to the following drawings and description. The components in the figures are not necessarily to scale, emphasis instead being placed upon illustrating the principles of the disclosure. Moreover, in the figures, like referenced numerals designate corresponding parts throughout the different views.

FIG. 1 is an example exploded view of a cellphone.

FIG. 2 is an example exploded view of a screen replacement assembly, according to an aspect of the disclosure.

FIG. 3 is an example view of a pin connector module, according to an aspect of the disclosure.

FIG. 4 is an example rear view of heat shield cover, according to an aspect of the disclosure.

FIG. 5 is an example flowchart of a process to replace a screen on an electronic device, according to an aspect of the disclosure.

### DETAILED DESCRIPTION

The following briefly describes the aspects of the disclosure in order to provide a basic understanding of some aspects of the disclosure. This brief description is not intended as an extensive overview. It is not intended to identify key or critical elements, or to delineate or otherwise narrow the scope. Its purpose is merely to present some concepts in a simplified form as a prelude to the more detailed description that is presented later.

The elements in the Figures interoperate as explained in more detail below. Before setting forth the detail explanation, however, it is noted that all of the discussion below, regardless of the particular implementation being described, is exemplary in nature, rather than limiting. For example, although selected aspects, features, or components of the implementations are depicted as being stored in memories, all or part of systems and methods consistent with the display systems may be stored on, distributed across, or read from other machine-readable media, for example, secondary storage devices such as hard disks, floppy disks, and CD-ROMs; a signal received from a network; or other forms of ROM or RAM either currently known or later developed.

Furthermore, although specific components of the architecture will be described, methods, systems, and articles of manufacture consistent with the architecture may include additional or different components. For example, a processor may be implemented as a microprocessor, microcontroller, application specific integrated circuit (ASIC), discrete logic, or a combination of other type of circuits or logic. Similarly, memories, may be DRAM, SRAM, Flash, or any other type of memory. Flags, data, databases, tables, and other data structures may be separately stored and managed, may be incorporated into a single memory or database, may be distributed, or may be logically and physically organized in many different ways. Programs may be parts of a single program, separate programs, or distributed across several memories and processors.

For purposes of this disclosure, and without limiting the disclosure, the term “cellphone” may be used interchangeably with each of “smartphone,” “mobile device,” “wearable device,” “smart watch,” “tablet,” “electronic device” or other mobile electronic devices that include a screen interface of some kind.

As known in the concept for making a cellphone screen easier to replace, it becomes apparent that the current methods for screen replacement represents one of the most common ways currently used to change the screen, with much difficulty. It resorts to the use of screws, screwdrivers and other pry tools, and it also requires some technical knowledge.

The present disclosure does not require the use of screws to insert/detach the screen nor does it require the use of tools, such as screwdrivers, heat guns or heating mats. Conventional methods also pose hazards such as accidental cuts caused by inserting or mishandling the aluminum or glass frame used to insert/attach the screen to the phone, and it does not encourage recycling, as the current market is flooded with cheap unrecyclable parts. The conventional methods are not user-friendly to the general public and may discourage people and stores from purchasing it.

Another problem with known methods is that the/their description as “convenient for replacement and assembly” is not accurate and not necessarily practical. The present disclosure can actually be used by the general public without any technical knowledge and it actually promotes the right to repair approach. Also, as opposed to conventional methods, users and companies benefit from the use of original screens from the manufacturer, which guarantees both quality to the customer and sales to the manufacturer, by minimizing or obliterating counterfeits and promoting the use of recyclable and original components, thus reducing pollution.

The goal is to have access to replacement phone screens at any shop, at any time, and to be able to change the non-functional or damaged screen with no previous experience, while guaranteeing the purchase of a genuine part. Most if not all the components needed for the system can be found in US soil.

The disclosed replacing part consists of a recyclable shaped-to-fit plastic mold and an LCD. The LCD is applied to the phone or detached from it by pressuring or lifting the mold.

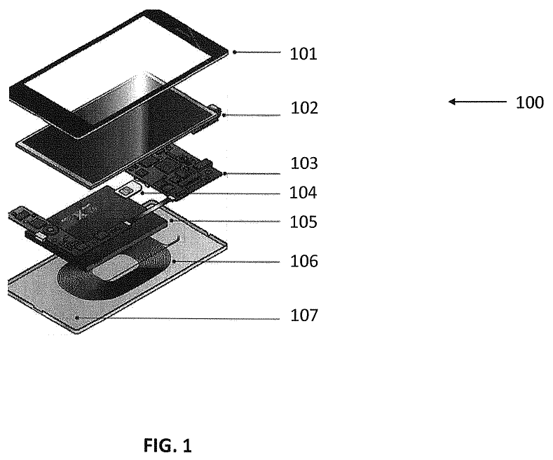

FIG. 1 illustrates an exploded view of a conventional cellphone assembly 100. The cellphone screen assembly includes a top enclosure 101, a screen assembly 102, a circuit board 103 for circuitry to provide functionality for the cellphone, a SIM Card 104, a battery 105, an induction coil 106 and a bottom enclosure 107. Not all cellphones or mobile electronic devices will have all the features shown in FIG. 1 or there may be additional features not illustrated. The disclosed method to repair a screen of an electronic device is related to the top enclosure 101, the screen assembly 102 and the bottom enclosure 107, in some aspects of the disclosure.

Repairing or upgrading electronic devices, such as cellphones or smartphones, often involve the use of screws, screwdrivers and other pry tools, and it also requires some technical knowledge or expertise that a conventional user may not possess or understand.

Prior art electronic device repair also poses hazards such as contact with broken glass, accidental cuts that may be happen when inserting or mishandling the aluminum frame used to insert/attach the screen to the phone, and it also does not encourage recycling, as the current market is flooded with cheap unrecyclable parts/waste. The prior art methods are not user-friendly to the general public and it may discourage people and stores from purchasing such devices.

The disclosed method for repairing and upgrading electronic devices may not require the use of screws to insert/detach the screen nor does it require the use of tools, such as screwdrivers, heat guns or heating mats. The disclosed method for repairing and upgrading electronic devices can actually be used by the general public without any technical knowledge and it actually encourages a do-it-yourself (“DIY”) approach. Also, users and companies benefit from the use of original screens from the manufacturer, which guarantees both quality to the customer and sales to the manufacturer, while minimizing or obliterating counterfeits and promoting the use of recycling material, thus reducing pollution.

The goal is to have access to replacement phone screens for the electronic device from any shop, at any time, and to be able to change the non-functional or damaged screen with no previous experience while guaranteeing the purchase of a genuine part.

The method for repairing and upgrading electronic devices, such as the screen of the electronic device, may be based on biometrics as first aspect. In another aspect, if the electronic device is not functional, a mechanical technique may be applied. In an aspect, the electronic device manufacturer may decide their preferred option. In an aspect, acts are taken to direct the electronic device to lift a damaged or undamaged screen, including the use of a remote control and/or apps, may be used. In an aspect, there should be no gap between the screen and the phone once the platform/screen is lifted.

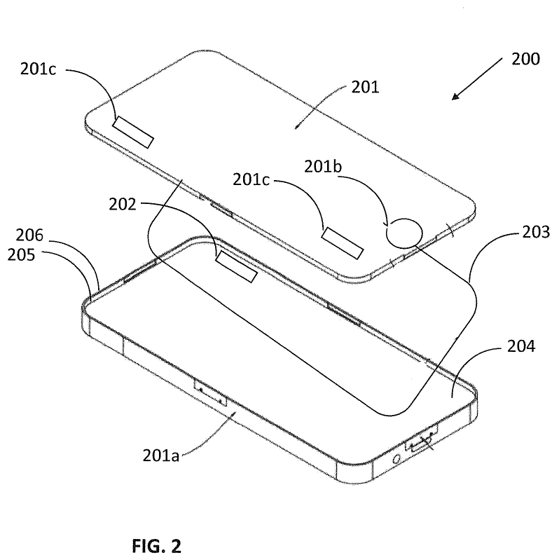

FIG. 2 illustrates an exploded view of an electronic device screen assembly 200 for convenient replacement In an aspect of the disclosure, to maximize ease of screen replacement, a display screen module, such as an LCD/screen module 201 of an electronic device 201a must not have any form of camera or microphone attached to it or any exposed cable/s. There should only be a physical connection between the screen and the phone, without the use of a flexible pin connector (“FPC”) female-male connectivity. In aspect, one or more pin connector modules 202 are used. In an aspect, a method to maximize convenience for replacing the screen module uses the pin connector module, where the pin connector module 202 includes a waterproof mating pad connector (pins to pad). In an aspect, the pin connector module 202 may be a pogo pin connector module. In an advantageous aspect, the pin connector module 202 may be a low-profile interposer module, such as that manufactured by Samtec®.

The method for repairing and upgrading electronic devices, such as the screen of the electronic device, may be based on a biometrics sensor 201b or one or more touch regions 201c, in communication with the display screen module 201 as first aspect. In an aspect, the biometrics sensor may be a touch fingerprint sensor, a visual face recognition sensor, a retinal scanner sensor or other biometric sensors known in the art. In another aspect, if the electronic device is not functional, a mechanical technique may be applied. In an aspect, the electronic device manufacturer may decide their preferred option. In an aspect, acts are taken to direct the electronic device to lift a damaged or undamaged screen, including the use of a remote control and/or apps, may be used. In an aspect, there should be no gap between the screen and the phone once the platform/screen is lifted.

In an aspect, a separator 203 between the phone and the screen comprises a water resistant and heat resistant material. The separator 203 should also have a clear-sealed view for cameras/face id, such as Gorilla Glass® or a similar transparent material product that matches its quality, transparency and water-resistance features.

In an aspect, screen/LCD flex cable(s) and chips or processors (not shown) related to the screen functioning should remain covered behind a heat/cover plate 204 (under the hood). In an aspect, the only item exposed should be the one or more pin connector modules 202, whose size and position may be determined by the manufacturer. In an aspect, to secure, seal and prevent water from penetrating the device, the repair module must come with a water and heat resistant plastic rim 205 that will fit into the cellphone's inner contour frame 206 when the screen 201 is inserted. In an aspect, PAI (polyamide-imide/torlon) is the recommended plastic for the inner frame contour 206. In addition, poron foam (which is a cushioning and absorbing material) could optionally surround the separator 203. If poron foam is not available, similar alternatives may be considered, such as parafix. The advantage of using foam is to prevent pressure spots from forming on the screen.

The inner contour of the phone will hold the screen secure through segments of magnets strategically placed as per the manufacture's design, and the inner contour of the screen should be made of metal. In an aspect, one or more pin connector modules 202 will also be magnetic and easy to detach.

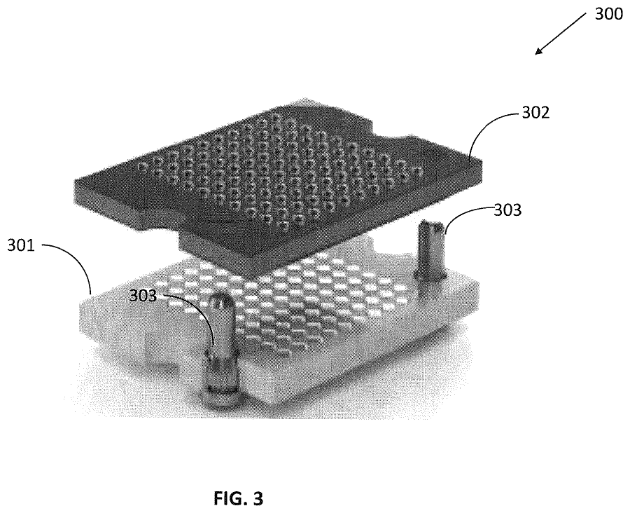

FIG. 3 is an example view of a pin connector module 300, according to an aspect of the disclosure. In an advantageous aspect, the pin connector module 300 may be a low-profile interposer module, or an ultra-low profile interposer module. In an aspect, reliable magnets are placed around the phone frame in strategic locations and sizes so that they do not interfere with any functions, while providing sufficient strength to keep the LCD/display attached to the phone part. It is important that the manufacturer considers providing strength to the rim to avoid dents. A successful connection is achieved by mating the ultra-low profile interposers by compression, matching a bottom surface 301 of the display 301 to a top surface 302 of the phone module with current low profile interposers 305, such as the Samtec® low-profile interposers line. Both sides of the interposers should have perfect alignment in order to minimize bad connections, and for general ease of use and handling comfort.

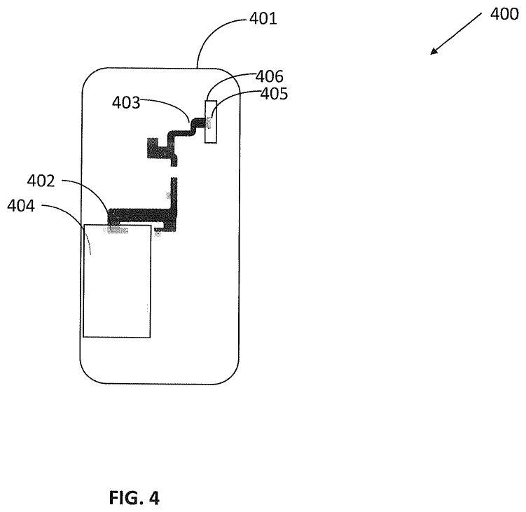

FIG. 4 illustrates an aspect of the electronic device screen assembly 400, as seen from behind heat/cover plate 401. In an aspect, a first end 402 of a flexible printed circuit (“FPC”) 403 is in communication with a motherboard 404 of the electronic device and a second end 405 in communication with one or more pin connector modules 406, directly or indirectly, by using any form of adaptor. The same applies to the screen. The FPC 403 must lay under the heat/cover plate 401, preventing the client from having accidental access to it.

Use of the methods disclosed in the application may have benefits, such as: guaranteed access to original screens; reduced chances of damaging different random parts of the phone significantly; increased revenue to manufacturer (incentivizing recycling and customer appreciation programs in routine swapping and cycling); user-friendly methods; environmentally friendly; recyclability; and reduced unwanted accidents with cellphone screens.

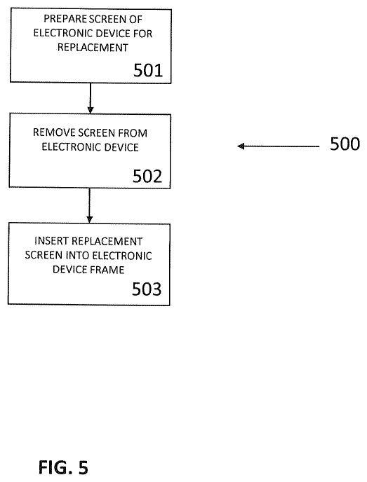

FIG. 5 is an example flowchart 500 of a process to replace a screen on an electronic device. In act 501, a user prepares the screen of the electronic device for replacement by directing the electronic device to lift the screen of the electronic device. In an aspect, may be based on a biometrics sensor 201b or one or more touch regions 201c as first aspect. In an aspect, the biometrics sensor may be a touch fingerprint sensor, a visual face recognition sensor, a retinal scanner sensor or other biometric sensors known in the art. In another aspect, if the electronic device is not functional, a mechanical technique may be applied. In an aspect, the electronic device manufacturer may decide their preferred option. In an aspect, act to direct the electronic device to lift a damaged or undamaged screen, including the use of a remote control and/or apps, may be used. In an aspect, there should be no gap between the screen and the phone once the platform/screen is lifted.

In act 502, the screen of the electronic device is removed from the electronic device. A replacement screen may be selected and presented for insertion of the replacement screen for the electronic device.

In act 503, the user inserts the replacement screen into the electronic device. The user will insert the screen into the cellphone's inner contour frame. In an aspect, a water and heat resistant plastic rim is contained within the cellphone's inner contour frame, such that the screen is placed in contact with the water and heat resistant plastic rim. In an aspect, a separator is present and placed before, or if attached to the screen, along with the screen into the inner contour frame, to provide a waterproof seal. In an aspect, the screen is in communication with one or more pin connector modules 202. In an aspect, a method to maximize convenience for replacing the screen module uses the pin connector module, where the pin connector module 202 includes a waterproof mating pad connector (pins to pad). In an advantageous aspect, the pin connector module 202 may be a low-profile interposer. In another aspect, the pin connection module 202 may be a pogo pin connector module.

While various aspects of the disclosure have been described, it will be apparent to those of ordinary skill in the art that many more aspects and implementations are possible within the scope of the disclosure. Accordingly, the disclosure is not to be restricted except in light of the attached claims and their equivalents.

What is claimed is:

1. An electronic device screen assembly of an electronic device for convenient replacement, the electronic device screen assembly comprising:
a display screen module;
a sensor in communication with the display screen module, the sensor configured to direct the electronic device to release the display screen module;
a separator in communication with the display screen module and positioned below the display screen module;
a heat resistant plastic rim in communication with an inner contour frame of the electronic device; the heat resistant plastic rim configured to accept the display screen module;
a heat cover in communication with the electronic device; and
one or more pin connector modules configured to connect the electronic device with the display screen module.

2. The electronic device screen assembly of claim 1, further comprising a flexible printed circuit disposed behind and upon the heat cover, the flexible printed circuit in communication with a motherboard via a first end of the flexible printed circuit in communication with one of the one or more pin connection modules via a second end of the flexible printed circuit board.

3. The electronic device screen assembly of claim 1, where the separator is water resistant and heat resistant.

4. The electronic device screen assembly of claim 1, where the separator comprises a transparent material.

5. The electronic device screen assembly of claim 1, where the inner frame contour comprises polyamide-imide/torlon, poron foam or parafix.

6. The electronic device screen assembly of claim 1, where the sensor comprises a biometrics sensor, a touch sensor, a visual face recognition sensor or a combination thereof.

7. The electronic device screen assembly of claim 1, further comprising an application configured to direct the electronic device to release the display screen module.

8. A method for replacing a display screen on an electronic device without use of external tools, the method comprising:
preparing the display screen of the electronic device for removal with a sensor configured to direct the electronic device to release the display screen;
removing the display screen from the electronic device; and
inserting a replacement display screen module onto the electronic device.

9. The method of claim 8, where preparing the display screen of the electronic device for removal comprises using a biometric sensor in communication with the electronic device and the display screen.

10. The method of claim 8, where inserting the replacement display screen module comprises inserting the replacement display screen module into an inner contour frame of the electronic device, such that a watertight seal is created between the replacement display screen module and the electronic device.

11. The method of claim 10, where the inner contour frame comprises polyamide-imide/torlon, poron foam or parafix.

12. The method of claim 8, where inserting the replacement display screen module comprises inserting a separator disposed below and in communication with a display screen disposed upon a top surface of the replacement display screen module.

13. The method of claim 8, where inserting the replacement display screen module comprises connecting the replacement display screen module with one or more pin connection modules.

14. The method of claim 13, where connecting the replacement display screen module with the one or more pin connection modules comprises connecting the replacement display screen module to a motherboard of the electronic device via a flexible printed circuit in communication with the replacement display screen module and the motherboard.

15. An article of manufacture comprising:
a display screen module of a cellphone;
a sensor in communication with the display screen module, the sensor configured to direct the cellphone to release the display screen module;
a separator in communication with the display screen module and positioned below the display screen module;
a heat resistant plastic rim in communication with an inner contour frame of the cellphone; the heat resistant plastic rim configured to accept the display screen module;
a heat cover in communication with the electronic device; and
one or more pin connector modules configured to connect the cellphone with the display screen module.

16. The article of manufacture of claim 15, further comprising a flexible printed circuit disposed behind and upon the heat cover, the flexible printed circuit in communication with a motherboard via a first end of the flexible printed circuit in communication with one of the one or more pin connection modules via a second end of the flexible printed circuit board.

17. The article of manufacture of claim 15, where the one or more pin connector modules comprises one or more low-profile pin connector modules.

18. The article of manufacture of claim 15, where the separator comprises a transparent material.

19. The article of manufacture of claim 15, where the inner frame contour comprises polyamide-imide/torlon, poron foam or parafix.

20. The article of manufacture of claim 15, where the sensor comprises a biometrics sensor, a touch sensor, a visual face recognition sensor or a combination thereof.
